(19) United States
(12) Patent Application Publication
(10) Pub. No.: US 2019/0393364 A1
(43) Pub. Date: Dec. 26, 2019

(54) ORGANIC SOLAR CELL

(71) Applicant: LG CHEM, LTD., Seoul (KR)

(72) Inventors: DOOWHAN CHOI, Daejeon (KR); JIYOUNG LEE, Daejeon (KR); BOGYU LIM, Daejeon (KR); SONGRIM JANG, Daejeon (KR); Jl HOON KIM, Daejeon (KR)

(21) Appl. No.: 16/479,137

(22) PCT Filed: May 28, 2018
(86) PCT No.: PCT/KR2018/006021

§ 371 Date: Jul. 18, 2019

(30) Foreign Application Priority Data
Jun. 27, 2017 (KR) 10-2017-0081181

(51) Int. Cl. H01L 31/0256; H01L 51/42; H01L 51/44

(52) U.S. Cl. CPC H01L 31/0256; H01L 51/4246; H01L 27/302; H01L 51/447; H01L 51/441

(57) ABSTRACT

The present specification relates to an organic solar cell including a first electrode; a second electrode disposed opposite to the first electrode; and one or more organic material layers disposed between the first electrode and the second electrode and including a photoactive layer, wherein the photoactive layer includes an electron donor and an electron acceptor, and the electron acceptor is a dual electron acceptor including both a fullerene-based compound and a non-fullerene-based compound.

### CROSS REFERENCE TO RELATED APPLICATIONS

This application is a 35 U.S.C. § 371 national stage application of PCT International Application No. PCT/KR2018/006021, filed May 28, 2018, which claims priority from Korean Patent Application Nos. 10-2017-0081181, filed Jun. 27, 2017, the contents of which are incorporated herein in their entireties by reference. The above-referenced PCT International Application was published in the Korean language as International Publication No. WO 2019/004605 A1 on Jan. 3, 2019.

### TECHNICAL FIELD

The present specification relates to an organic solar cell.

### BACKGROUND ART

An organic solar cell is a device capable of directly converting solar energy to electric energy by applying a photovoltaic effect. Solar cells are divided into inorganic solar cells and organic solar cells depending on the materials forming a thin film, and since existing inorganic solar cells already have limits in economic feasibility and material supplies, organic solar cells that are readily processed, inexpensive and have various functions have been highly favored as a long-term alternative energy source.

As an electron acceptor material used in a photoactive layer of an organic solar cell, fullerene-based compounds have been mainly used, and recently, studies on non-fullerene-based compounds capable of changing an absorption area have been actively ongoing.

However, non-fullerene-based compounds exhibit favorable efficiency only in combination with specific electron donor materials, and therefore, overcoming such limitations has been an important challenge.

### DISCLOSURE

### Technical Problem

The present specification is directed to providing an organic solar cell.

### Technical Solution

One embodiment of the present specification provides an organic solar cell including a first electrode; a second electrode disposed opposite to the first electrode; and one or more organic material layers disposed between the first electrode and the second electrode and including a photoactive layer, wherein the photoactive layer includes an electron donor and an electron acceptor, and the electron acceptor is a dual electron acceptor including both a fullerene-based compound and a non-fullerene-based compound.

### Advantageous Effects

An organic solar cell according to one embodiment of the present specification has excellent energy conversion efficiency by using a dual electron acceptor including both a fullerene-based compound and a non-fullerene-based compound as an electron acceptor of a photoactive layer.

### DESCRIPTION OF DRAWINGS

FIG. 1 is a diagram illustrating an organic solar cell according to one embodiment of the present specification.

FIG. 2 is a diagram presenting voltage-dependent current density of organic solar cells of Example 3, Comparative Example 1 and Comparative Example 2 of the present specification.

FIG. 3 is a diagram presenting voltage-dependent current density of organic solar cells of Example 6, Comparative Example 3 and Comparative Example 4.

FIG. 4 is a diagram presenting an NMR spectrum of Chemical Formula J synthesized in Preparation Example 1.

FIG. 5 is a diagram presenting an NMR spectrum of Chemical Formula J-1 synthesized in Preparation Example 1.

FIG. 6 is a diagram presenting an NMR spectrum of Chemical Formula K synthesized in Preparation Example 1.

FIG. 7 is a diagram presenting a UV-vis absorption spectrum of Polymer 1 synthesized in Preparation Example 1.

FIG. 8 is a diagram presenting a UV-vis absorption spectrum of Polymer 2 synthesized in Preparation Example 2.

### REFERENCE NUMERAL

101: First Electrode
102: Electron Transfer Layer
103: Photoactive Layer
104: Hole Transfer Layer
105: Second Electrode

### MODE FOR DISCLOSURE

Hereinafter, the present specification will be described in more detail.

One embodiment of the present specification provides an organic solar cell including a first electrode; a second electrode disposed opposite to the first electrode; and one or more organic material layers disposed between the first electrode and the second electrode and including a photoactive layer, wherein the photoactive layer includes an electron donor and an electron acceptor, and the electron acceptor is a dual electron acceptor including both a fullerene-based compound and a non-fullerene-based compound.

In the present specification, a description of a certain part ‘including’ certain constituents means capable of further including other constituents, and does not exclude other constituents unless particularly stated on the contrary.

In the present specification, a ‘unit’ is a repeated structure included in a monomer of a polymer, and means a structure in which the monomer bonds in the polymer by polymerization.

In the present specification, the meaning of ‘including a unit’ means being included in a main chain in a polymer.

Examples of the substituents are described below, however, the substituents are not limited thereto.

In the present specification,

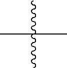

means a site linked to other substituents, monomers or bonding sites.

The term ‘substitution’ means a hydrogen atom bonding to a carbon atom of a compound is changed to another substituent, and the position of substitution is not limited as long as it is a position at which the hydrogen atom is substituted, that is, a position at which a substituent can substitute, and when two or more substituents substitute, the two or more substituents may be the same as or different from each other.

The term ‘substituted or unsubstituted’ in the present specification means being substituted with one or more substituents selected from the group consisting of deuterium; a halogen group; a nitrile group; a nitro group; a hydroxyl group; a substituted or unsubstituted alkyl group; a substituted or unsubstituted cycloalkyl group; a substituted or unsubstituted alkoxy group; a substituted or unsubstituted aryloxy group; a substituted or unsubstituted alkenyl group; a substituted or unsubstituted aryl group; and a substituted or unsubstituted heterocyclic group, or being substituted with a substituent linking two or more substituents among the substituents illustrated above, or having no substituents. For example, ‘a substituent linking two or more substituents’ may include a biphenyl group. In other words, a biphenyl group may be an aryl group, or interpreted as a substituent linking two phenyl groups.

In the present specification, examples of the halogen group include fluorine, chlorine, bromine or iodine.

In the present specification, the alkyl group may be linear or branched, and although not particularly limited thereto, the number of carbon atoms is preferably from 1 to 50. Specific examples thereof may include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylhexyl, 4-methylhexyl, 5-methylhexyl and the like, but are not limited thereto.

In the present specification, the cycloalkyl group is not particularly limited, but preferably has 3 to 60 carbon atoms, and specific examples thereof may include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl and the like, but are not limited thereto.

In the present specification, the alkoxy group may be linear, branched or cyclic. The number of carbon atoms of the alkoxy group is not particularly limited, but is preferably from 1 to 20. Specific examples thereof may include methoxy, ethoxy, n-propoxy, isopropoxy, i-propyloxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy, benzyloxy, p-methylbenzyloxy and the like, but are not limited thereto.

In the present specification, the alkenyl group may be linear or branched, and although not particularly limited thereto, the number of carbon atoms is preferably from 2 to 40. Specific examples thereof may include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group and the like, but are not limited thereto.

In the present specification, when the aryl group is a monocyclic aryl group, the number of carbon atoms is not particularly limited, but is preferably from 6 to 25. Specific examples of the monocyclic aryl group may include a phenyl group, a biphenyl group, a terphenyl group and the like, but are not limited thereto.

In the present specification, when the aryl group is a polycyclic aryl group, the number of carbon atoms is not particularly limited, but is preferably from 10 to 24. Specific examples of the polycyclic aryl group may include a naphthyl group, an anthracenyl group, a phenanthryl group, a pyrenyl group, a perylenyl group, a chrysenyl group, a fluorenyl group and the like, but are not limited thereto.

In the present specification, the fluorenyl group may be substituted, and adjacent substituents may bond to each other to form a ring.

In the present specification, the arylene group means the aryl group having two bonding sites, that is, a divalent group. Descriptions on the aryl group provided above may be applied thereto except for these each being divalent.

In the present specification, the heterocyclic group is a group including one or more atoms that are not carbon, that is, heteroatoms, and specifically, the heteroatom may include one or more atoms selected from the group consisting of O, N, Se, S and the like. The number of carbon atoms of the heterocyclic group is not particularly limited, but is preferably from 2 to 60. Examples of the heterocyclic group may include a thiophene group, a furan group, a pyrrole group, an imidazole group, a thiazole group, an oxazole group, an oxadiazole group, a triazole group, a pyridyl group, a bipyridyl group, a pyrimidyl group, a triazine group, a triazole group, an acridyl group, a pyridazine group, a pyrazinyl group, a quinolinyl group, a quinazoline group, a quinoxalinyl group, a phthalazinyl group, an isoquinoline group, an indole group, a carbazole group, a benzoxazole group, a benzimidazole group, a benzothiazole group, a benzocarbazole group, a benzothiophene group, a dibenzothiophene group, a benzofuranyl group, a phenanthroline group, a thiazolyl group, an isoxazolyl group, an oxadiazolyl group, a thiadiazolyl group, a phenothiazinyl group, a dibenzofuranyl group and the like, but are not limited thereto.

In the present specification, the aryl group of the aryloxy group is the same as the examples of the aryl group described above. Specifically, examples of the aryloxy group may include phenoxy, p-tolyloxy, m-tolyloxy, 3,5-dimethyl-phenoxy, 2,4,6-trimethylphenoxy, p-tert-butylphenoxy, 3-biphenyloxy, 4-biphenyloxy, 1-naphthyloxy, 2-naphthyloxy, 4-methyl-1-naphthyloxy, 5-methyl-2-naphthyloxy, 1-anthryloxy, 2-anthryloxy, 9-anthryloxy, 1-phenanthryloxy, 3-phenanthryloxy, 9-phenanthryloxy and the like, examples of the arylthioxy group may include a phenylthioxy group, a 2-methylphenylthioxy group, a 4-tert-butylphenylthioxy group and the like, and examples of the arylsulfoxy group may include a benzenesulfoxy group, a p-toluenesulfoxy group and the like, however, the aryloxy group, the arylthioxy group and the arylsulfoxy group are not limited thereto.

In the present specification, the ‘fullerene-based compound’ means a soccer ball-shaped molecule formed by carbon atoms forming pentagonal and hexagonal shapes being linked to each other.

In the present specification, the ‘non-fullerene-based compound’ means a compound that is not the fullerene-based compound.

The fullerene-based compound is a material commonly used as an electron acceptor of an organic solar cell, but only absorbs light in an ultraviolet region, and aggregates together. Accordingly, using a fullerene-based compound alone as an electron acceptor of an organic solar cell affects morphology of a photoactive layer leading to a disadvantage of reducing a device lifetime.

On the other hand, a non-fullerene-based compound may be transformed into various structures as well as capable of controlling an energy band gap, and therefore, may perform a role of improving device lifetime and efficiency. However, there is still a limit that it is activated with only a small number of electron donor materials.

By using both a fullerene-based compound and a non-fullerene-based compound, the organic solar cell according to one embodiment of the present specification may enhance efficiency of the organic solar cell by complementing each other's disadvantages.

In one embodiment of the present specification, the fullerene-based compound may be any one of the following [6,6]-phenyl-C₆₁-butyric acid methyl ester (PC₆₁BM), [6,6]-phenyl-C₇₁-butyric acid methyl ester (PC₇₁BM), mono-o-quino-dimethane C₆₀ (mono-oQDMC₆₀), bis-o-quino-dimethane C₆₀ (bis-oQDMC₆₀), indene-C₆₀-bis-adduct (ICBA) and bis-[6,6]-phenyl-C₆₁-butyric acid methyl ester (bis-PCBM).

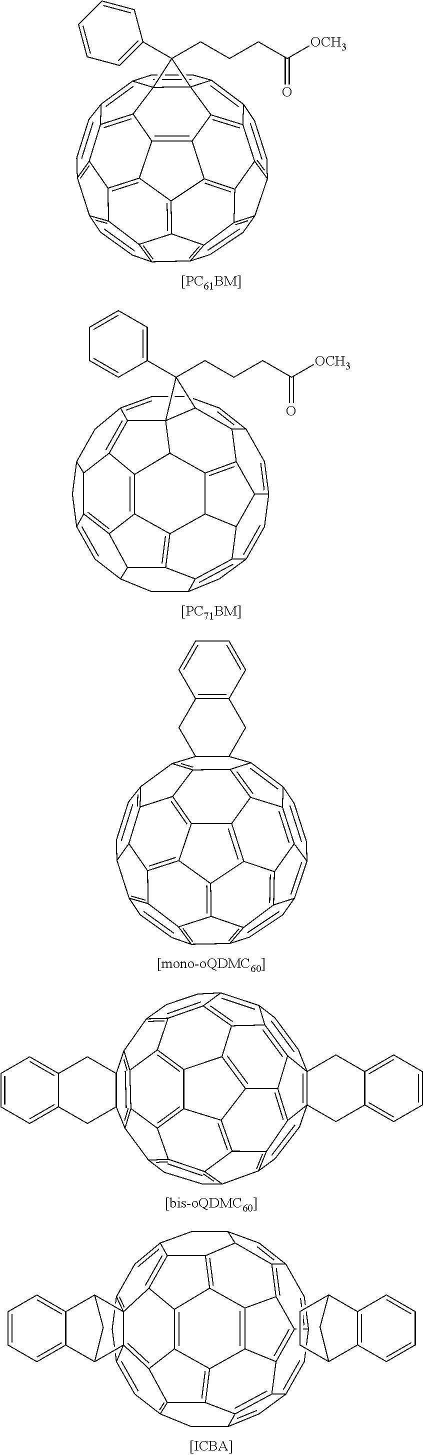

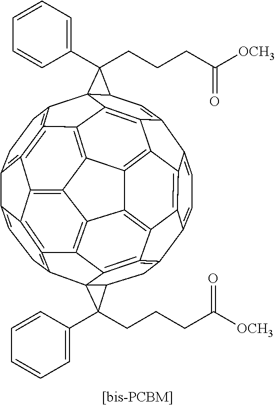

In one embodiment of the present specification, the non-fullerene-based compound may be represented by the following Chemical Formula A.

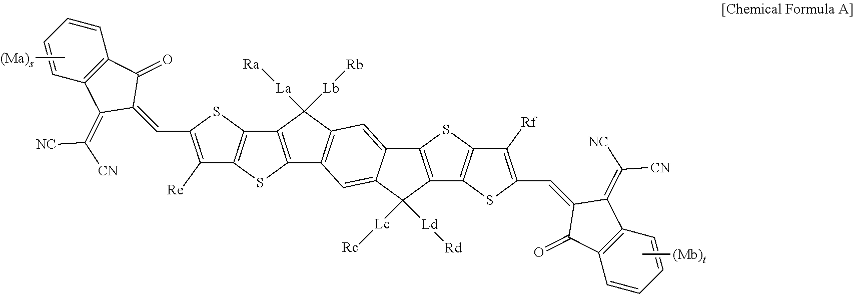

In Chemical Formula A,

Ra to Rf are the same as or different from each other, and each independently hydrogen; or a substituted or unsubstituted alkyl group,

La to Ld are the same as or different from each other, and each independently a substituted or unsubstituted arylene group; or a substituted or unsubstituted divalent heterocyclic group,

Ma and Mb are the same as or different from each other, and each independently hydrogen; a halogen group; or a substituted or unsubstituted alkyl group,

s and t are the same as or different from each other, and each independently an integer of 0 to 2, and

when s or t is each 2, structures in the parentheses are the same as each other.

In one embodiment of the present specification, Ra to Rd are each an alkyl group.

In another embodiment, Ra to Rd are each an alkyl group having 1 to 30 carbon atoms.

In another embodiment, Ra to Rd are each an alkyl group having 1 to 10 carbon atoms.

In one embodiment of the present specification, Re and Rf are hydrogen.

In one embodiment of the present specification, La to Ld are each an arylene group.

In another embodiment, La to Ld are each an arylene group having 6 to 25 carbon atoms.

In another embodiment, La to Ld are a phenylene group.

In another embodiment, La to Ld are each a divalent heterocyclic group.

In another embodiment, La to Ld are each a divalent heterocyclic group having 2 to 30 carbon atoms.

In another embodiment, La to Ld are each a divalent heterocyclic group having 2 to 10 carbon atoms.

In another embodiment, La to Ld are a divalent thiophene group.

In one embodiment of the present specification, Ma and Mb are hydrogen.

In another embodiment, Ma and Mb are each an alkyl group.

In another embodiment, Ma and Mb are each an alkyl group having 1 to 10 carbon atoms.

In another embodiment, Ma and Mb are a methyl group.

In another embodiment, Ma and Mb are each a halogen group.

In another embodiment, Ma and Mb are fluorine.

In one embodiment of the present specification, s and t are 0.

In another embodiment, s and t are 1.

In another embodiment, s and t are 2.

In one embodiment of the present specification, the non-fullerene-based compound is any one of the following Chemical Formulae A-1 to A-5.

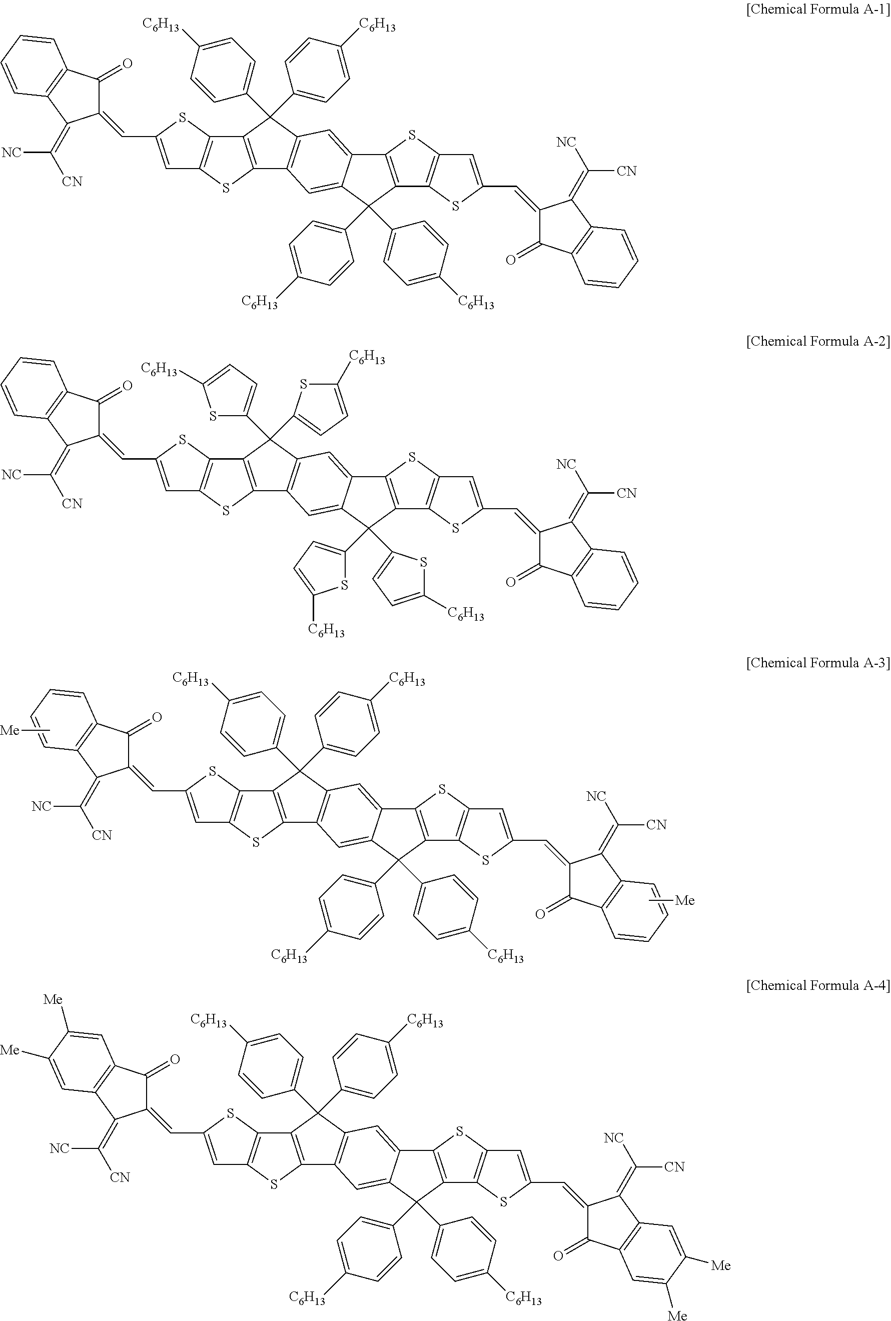

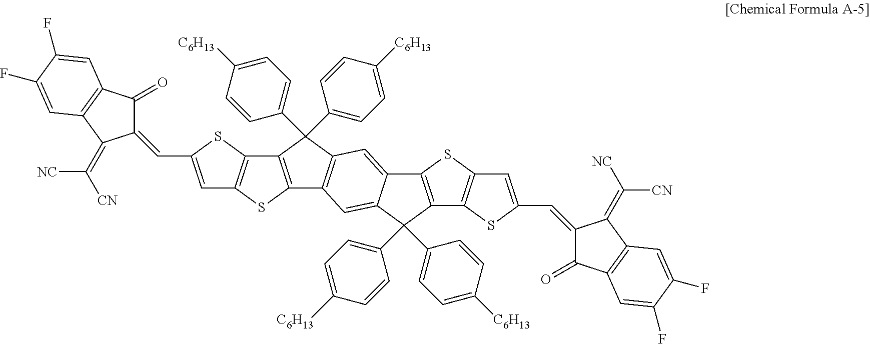

In the present specification, Me means a methyl group.

In another embodiment of the present specification, the non-fullerene-based compound is the compound represented by Chemical Formula A-1.

In one embodiment of the present specification, the electron donor includes a polymer including a first unit represented by the following Chemical Formula 1; and a second unit represented by the following Chemical Formula 2.

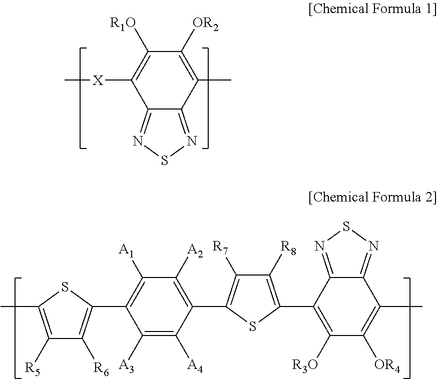

In Chemical Formulae 1 and 2,

X is the following Chemical Formula 3 or 4,

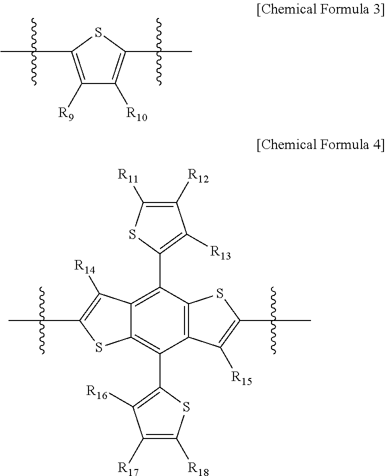

R₁ to R₄ are the same as or different from each other, and each independently a substituted or unsubstituted alkyl group; or a substituted or unsubstituted aryl group,

R₅ to R₁₈ are the same as or different from each other, and each independently hydrogen; deuterium; a halogen group; a nitrile group; a nitro group; a hydroxyl group; a substituted or unsubstituted alkyl group; a substituted or unsubstituted cycloalkyl group; a substituted or unsubstituted alkoxy group; a substituted or unsubstituted aryloxy group; a substituted or unsubstituted alkenyl group; a substituted or unsubstituted aryl group; or a substituted or unsubstituted heterocyclic group, and

A₁ to A₄ are the same as or different from each other, and each independently hydrogen, fluorine or chlorine, and at least one of A₁ to A₄ is fluorine or chlorine.

In one embodiment of the present specification, R₁ to R₄ are each a substituted or unsubstituted alkyl group; or a substituted or unsubstituted aryl group.

In one embodiment of the present specification, R₁ to R₄ are each an alkyl group having 1 to 30 carbon atoms.

In one embodiment of the present specification, R₁ to R₄ are each an aryl group having 6 to 30 carbon atoms.

In one embodiment of the present specification, R₅ to R₁₈ are each hydrogen; or a substituted or unsubstituted alkyl group.

In one embodiment of the present specification, R₅ to R₁₀ and R₁₂ to R₁₇ are hydrogen.

In one embodiment of the present specification, R₁₁ and R₁₈ are each a substituted or unsubstituted alkyl group.

In one embodiment of the present specification, R₁₁ and R₁₈ are each an alkyl group having 1 to 30 carbon atoms.

In one embodiment of the present specification, at least two or more of A₁ to A₄ are fluorine or chlorine.

In one embodiment of the present specification, A₁ and A₄ are fluorine.

In one embodiment of the present specification, A₁ and A4 are chlorine.

In one embodiment of the present specification, the polymer includes a unit represented by the following Chemical Formula 5.

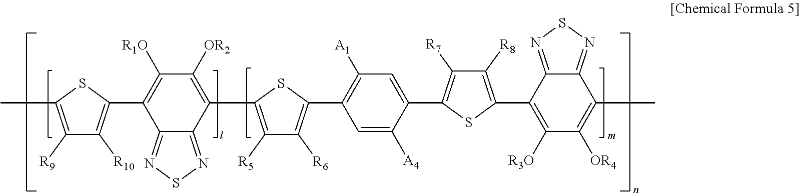

In Chemical Formula 5,

R₁ to R₄ have the same definitions as in Chemical Formulae 1 and 2,

R₅ to R₁₀ have the same definitions as in Chemical Formulae 2 and 3,

A₁ and A₄ have the same definitions as in Chemical Formula 2,

l is, as a mole fraction, a real number of 0<l<1,

m is, as a mole fraction, a real number of 0<m<1,

l+m=¹, and

n is, as a unit repetition number, an integer of 1 to 10,000.

In one embodiment of the present specification, R₁ to R₄ are an alkyl group having 1 to 30 carbon atoms.

In another embodiment, R₁ to R₄ are an alkyl group having 1 to 15 carbon atoms.

In one embodiment of the present specification, R₅ to R₁₀ are hydrogen.

In one embodiment of the present specification, A₁ and A₄ are fluorine.

In one embodiment of the present specification, 1 is 0.5.

In one embodiment of the present specification, m is 0.5.

In one embodiment of the present specification, the polymer includes a unit represented by the following Chemical Formula 5-1.

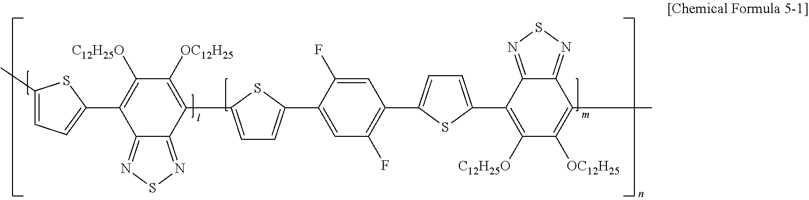

In Chemical Formula 5-1,1, m and n have the same definitions as in Chemical Formula 5.

In one embodiment of the present specification, the polymer includes a unit represented by the following Chemical Formula 6.

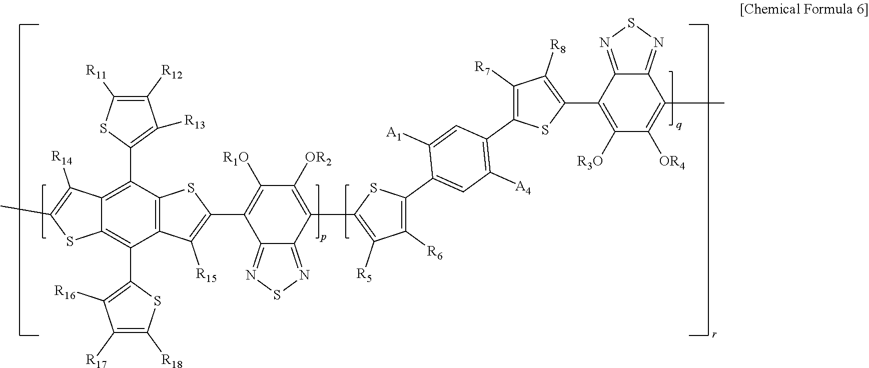

In Chemical Formula 6,

R₁ to R₄ have the same definitions as in Chemical Formulae 1 and 2,

R₅ to R₈ and R₁₁ to R₁₈ have the same definitions as in Chemical Formulae 2 and 4,

A₁ and A₄ have the same definitions as in Chemical Formula 2,

p is, as a mole fraction, a real number 0<p<1,

q is, as a mole fraction, a real number of 0<q<1,

p+q=1, and

r is, as a unit repetition number, an integer of 1 to 10,000.

In one embodiment of the present specification, R₁ to R₄ are each an alkyl group having 1 to 30 carbon atoms.

In one embodiment of the present specification, R₁ to R₄ are each an alkyl group having 1 to 15 carbon atoms.

In one embodiment of the present specification, R₁₁ and R₁₈ are each an alkyl group having 1 to 30 carbon atoms.

In one embodiment of the present specification, R₁₁ and R₁₈ are each an alkyl group having 1 to 15 carbon atoms.

In one embodiment of the present specification, R₅ to R₈ and R₁₂ to R₁₇ are hydrogen.

In one embodiment of the present specification, A₁ and A₄ are fluorine.

In one embodiment of the present specification, p is 0.5.

In one embodiment of the present specification, q is 0.5.

In one embodiment of the present specification, the polymer includes a unit represented by the following Chemical Formula 6-1.

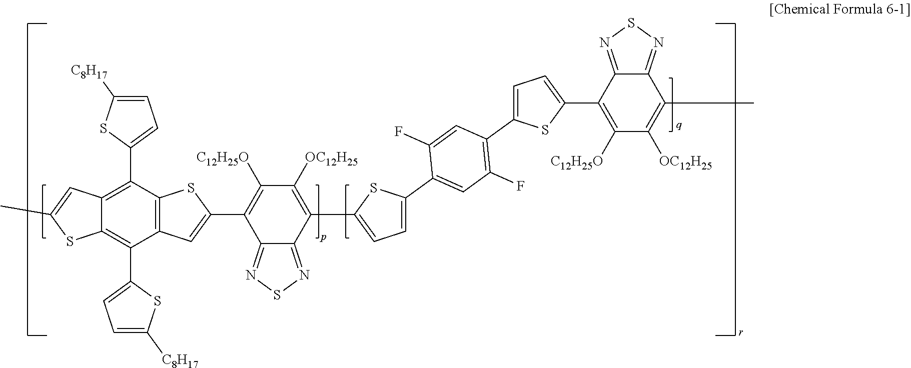

In Chemical Formula 6-1, p, q and r have the same definitions as in Chemical Formula 6.

In one embodiment of the present specification, the electron donor is the polymer represented by Chemical Formula 5, the fullerene-based compound of the electron acceptor is PC₇₁BM, and the non-fullerene-based compound of the electron acceptor may be the compound represented by Chemical Formula A-1.

In one embodiment of the present specification, the fullerene-based compound and the non-fullerene-based compound have a mass ratio of 1.8:0.2 to 0.2:1.8.

In one embodiment of the present specification, when the electron donor is the polymer represented by Chemical Formula 5, the fullerene-based compound and the non-fullerene-based compound have a mass ratio of 1.6:0.4 to 0.5:1.5, preferably 1.2:0.8 to 0.5:1.5, and more preferably 1.2:0.8 to 0.8:1.2.

In one embodiment of the present specification, the electron donor is the polymer represented by Chemical Formula 6, the fullerene-based compound of the electron acceptor is PC₇₁BM, and the non-fullerene-based compound of the electron acceptor may be the compound represented by Chemical Formula A-1.

In one embodiment of the present specification, when the electron donor is the polymer represented by Chemical Formula 6, the fullerene-based compound and the non-fullerene-based compound have a mass ratio of 1.2:0.8 to 0.2:1.8, preferably 1.2:0.8 to 0.4:1.6, and more preferably 0.8:1.2 to 0.4:1.6.

In one embodiment of the present specification, the electron donor and the electron acceptor have a mass ratio of 1:1 to 1:4. The ratio is preferably from 1:1.5 to 1:2.5, and more preferably from 1:1.8 to 1:2.2.

In one embodiment of the present specification, the polymer is a random polymer. In addition, when the polymer is a random polymer, solubility is enhanced, which is economically effective cost-wise in terms of a device manufacturing process.

In one embodiment of the present specification, an end group of the polymer is a substituted or unsubstituted heterocyclic group; or a substituted or unsubstituted aryl group.

In one embodiment of the present specification, an end group of the polymer is a 4-(trifluoromethyl)phenyl group.

In one embodiment of the present specification, an end group of the polymer is a bromo-thiophene group.

In another embodiment, an end group of the polymer is a trifluoro-benzene group.

According to one embodiment of the present specification, the polymer preferably has a number average molecular weight of 5,000 g/mol to 1,000,000 g/mol.

According to one embodiment of the present specification, the polymer may have molecular weight distribution of 1 to 10. The polymer preferably has molecular weight distribution of 1 to 3.

Electrical properties and mechanical properties become better as the molecular weight distribution decreases and the number average molecular weight increases.

In addition, the number average molecular weight is preferably 100,000 g/mol or less so that a solution coating method is favorably used by having solubility of certain level or higher.

The polymer may be prepared by introducing monomers of each unit with Pd₂(dba)₃ and P(o-tolyl)₃ with chlorobenzene as a solvent, and polymerizing the result using a microwave reactor.

The polymer according to the present specification may be prepared through a multi-step chemical reaction. After preparing monomers through an alkylation reaction, a Grignard reaction, a Suzuki coupling reaction, a Stille coupling reaction and the like, final polymers may be prepared through a carbon-carbon coupling reaction such as a Stille coupling reaction. When a substituent to introduce is a boronic acid or boronic ester compound, the polymer may be prepared through a Suzuki coupling reaction, and when a substituent to introduce is a tributyltin or trimethyltin compound, the polymer may be prepared through a Stille coupling reaction, however, the preparation is not limited thereto.

An organic solar cell according to one embodiment of the present specification includes a first electrode, a photoactive layer and a second electrode. the organic solar cell may further include a substrate, a hole transfer layer and/or an electron transfer layer.

In one embodiment of the present specification, when the organic solar cell receives photons from an external light source, electrons and holes are generated between an electron donor and an electron acceptor. The generated holes are transferred to an anode through an electron donor layer.

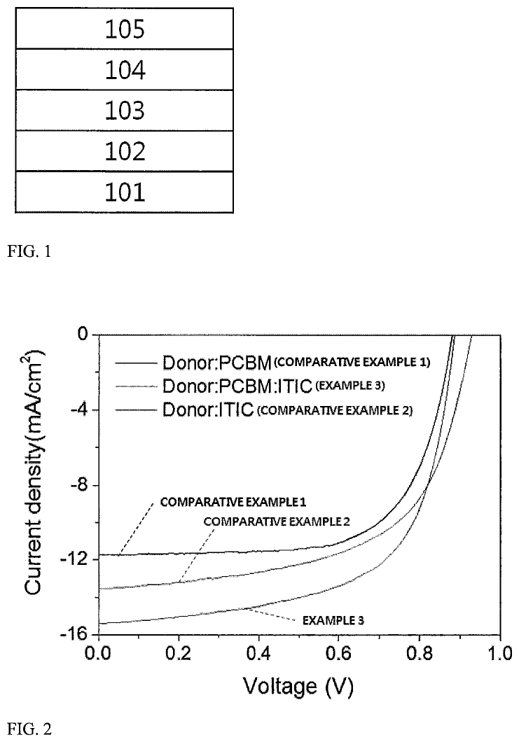

FIG. 1 is a diagram illustrating an organic solar cell according to one embodiment of the present specification including a first electrode (101), an electron transfer layer (102), a photoactive layer (103), a hole transfer layer (104) and a second electrode (105).

In one embodiment of the present specification, the organic solar cell may further include additional organic material layers. The organic solar cell may reduce the number of organic material layers by using organic materials having various functions at the same time.

In one embodiment of the present specification, in the organic solar cell, the layers may be arranged in the order of a cathode, a photoactive layer and an anode, or may also be arranged in the order of an anode, a photoactive layer and a cathode, however, the disposition is not limited thereto.

In another embodiment, in the organic solar cell, the layers may be arranged in the order of an anode, a hole transfer layer, a photoactive layer, an electron transfer layer and a cathode, or may also be arranged in the order of a cathode, an electron transfer layer, a photoactive layer, a hole transfer layer and an anode, however, the disposition is not limited thereto.

In one embodiment of the present specification, the organic solar cell has a normal structure. In the normal structure, the layers may be laminated in the order of a substrate, a first electrode, a hole transfer layer, an organic material layer including a photoactive layer, an electron transfer layer and a second electrode.

In one embodiment of the present specification, the organic solar cell has an inverted structure. In the inverted structure, the layers may be laminated in the order of a substrate, a first electrode, an electron transfer layer, an organic material layer including a photoactive layer, a hole transfer layer and a second electrode.

In one embodiment of the present specification, the first electrode is an anode, and the second electrode is a cathode. In another embodiment, the first electrode is a cathode, and the second electrode is an anode.

In the present specification, a description of one member being placed ‘on’ another member includes not only a case of the one member adjoining the another member but a case of still another member being present between the two members.

In the present specification, an energy level means magnitude of energy. Accordingly, even when an energy level is expressed in a negative (−) direction from a vacuum level, the energy level is interpreted to mean an absolute value of the corresponding energy value. For example, a HOMO energy level means a distance from a vacuum level to a highest occupied molecular orbital. In addition, a LUMO energy level means a distance from a vacuum level to a lowest unoccupied molecular orbital.

In one embodiment of the present specification, the organic solar cell has a tandem structure. In this case, the organic solar cell may include two or more layers of photoactive layers. The organic solar cell according to one embodiment of the present specification may have a photoactive layer in one, or two or more layers.

In another embodiment, a buffer layer may be disposed between a photoactive layer and a hole transfer layer, or between a photoactive layer and an electron transfer layer. Herein, a hole injection layer may be further disposed between an anode and the hole transfer layer. In addition, an electron injection layer may be further disposed between a cathode and the electron transfer layer.

In one embodiment of the present specification, the electron donor and the electron acceptor form a bulk heterojunction (BHJ).

A bulk heterojunction means an electron donor material and an electron acceptor material being mixed together in a photoactive layer.

In one embodiment of the present specification, the photoactive layer further includes an additive.

In one embodiment of the present specification, the additive has a molecular weight of 50 g/mol to 300 g/mol.

In another embodiment, the additive is an organic material having a boiling point of 30° C. to 300° C.

In the present specification, the organic material means a material including at least one or more carbon atoms.

In one embodiment, the additive may further include one or more types of additives among additives selected from the group consisting of 1,8-diiodooctane (DIO), 1-chloronaphthalene (1-CN), diphenyl ether (DPE), octanedithiol and tetrabromothiophene.

In one embodiment of the present specification, the photoactive layer has a bilayer structure including an n-type organic material layer and a p-type organic material layer, and the p-type organic material layer includes the polymer.

The substrate in the present specification may include a glass substrate or a transparent plastic substrate having excellent transparency, surface smoothness, handling easiness and water resistance, but is not limited thereto, and substrates typically used in organic solar cells may be used without limit. Specific examples thereof include glass, polyethylene terphthalate (PET), polyethylene naphthalate (PEN), polypropylene (PP), polyimide (PI), triacetyl cellulose (TAC) and the like, but are not limited thereto.

A material of the first electrode may include a material that is transparent and has excellent conductivity, however, the material is not limited thereto. Examples thereof may include metals such as vanadium, chromium, copper, zinc or gold, or alloys thereof; metal oxides such as zinc oxide, indium oxide, indium tin oxide (ITO) or indium zinc oxide (IZO); combinations of metals and oxides such as ZnO:Al or SnO₂:Sb; conductive polymers such as poly(3-methylthiophene), poly[3,4-(ethylene-1,2-dioxy)thiophene] (PEDOT), polypyrrole and polyaniline, and the like, but are not limited thereto.

A method of forming the first electrode is not particularly limited, however, a method of, for example, sputtering, E-beam, thermal deposition, spin coating, screen printing, inkjet printing, doctor blade or gravure printing may be used.

When forming the first electrode on a substrate, the result may go through processes of cleaning, dehydrating and modifying to be hydrophilic.

For example, after a patterned ITO substrate is cleaned with a cleaning agent, acetone and isopropyl alcohol (IPA) in consecutive order, the ITO substrate is dried for 1 minute to 30 minutes at 100° C. to 150° C., preferably for 10 minutes at 120° C., on a heating plate in order to dehydrate, and when the substrate is completely cleaned, the surface of the substrate is modified to be hydrophilic.

Through the surface modification such as above, the junctional surface potential may be maintained at a level suitable as surface potential of a photoactive layer. In addition, when a surface is modified, a polymer thin film may be readily formed on a first electrode, and the quality of the thin film may be improved.

Preprocessing technologies for the first electrode include a) a surface oxidation method using parallel plate discharge, b) a method of oxidizing the surface through ozone generated using UV rays in a vacuum state, and c) an oxidation method using oxygen radicals generated by plasma.

One of the methods described above may be selected depending on the condition of the first electrode or the substrate. However, it is commonly preferred to prevent the leave of oxygen on the surface of the first electrode or the substrate and to suppress the remaining of moisture and organic materials as much as possible, no matter which method is used. Practical effects of the preprocessing may be maximized in this case.

As a specific example, a method of oxidizing the surface through ozone generated using UV may be used. Herein, a patterned ITO substrate may be fully dried by baking the patterned ITO substrate on a hot plate after being ultrasonic cleaned, and the patterned ITO substrate is introduced into a chamber and then may be cleaned by the ozone generated by reacting oxygen gas with UV light using a UV lamp.

However, the method of surface modification of the patterned ITO substrate in the present specification is not particularly limited, and any method oxidizing a substrate may be used.

The second electrode may include a metal having small work function, but is not limited thereto. Specific examples thereof may include metals such as magnesium, calcium, sodium, potassium, titanium, indium, yttrium, lithium, gadolinium, aluminum, silver, tin and lead, or alloys thereof; or multilayer-structured materials such as LiF/Al, LiO₂/Al, LiF/Fe, Al:Li, Al:BaF₂ and A:BaF₂:Ba, but are not limited thereto.

The second electrode may be formed by being deposited inside a thermal depositor having a vacuum degree of 5×10⁻⁷ torr or less, however, the formation is not limited to this method.

The hole transfer layer and/or the electron transfer layer play a role of efficiently transferring the electrons and the holes separated in a photoactive layer to an electrode, and the material is not particularly limited.

The hole transfer layer material may include poly(3,4-ethylenedioxythiophene) doped with poly(styrenesulfonic acid) (PEDOT:PSS), molybdenum oxide (MoOₓ); vanadium oxide (V₂O₅); nickel oxide (NiO); tungsten oxide (WOₓ) and the like, but is not limited thereto.

The electron transfer layer material may include electron-extracting metal oxides, and may specifically include a metal complex of 8-hydroxyquinoline; a complex including Alq₃; a metal complex including Liq; LiF; Ca; titanium oxide (TiOₓ); zinc oxide (ZnO); cesium carbonate (Cs₂CO₃), and the like, but is not limited thereto.

The photoactive layer may be formed by dissolving a photoactive material such as an electron donor and/or an electron acceptor in an organic solvent, and then applying the solution using a method such as spin coating, dip coating, screen printing, spray coating, doctor blade or brush painting, however, the method is not limited thereto.

Hereinafter, the present specification will be described in detail with reference to examples in order to specifically describe the present specification. However, examples according to the present specification may be modified to various different forms, and the scope of the present specification is not construed as being limited to the examples described below. The examples of the present specification are provided in order to more fully describe the present specification to those having average knowledge in the art.

### Preparation Example 1: Synthesis of Polymer 1

(1) Synthesis of Chemical Formula J

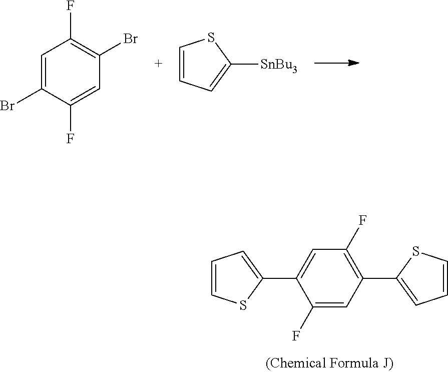

After introducing toluene to two starting materials and adding 0.05 equivalents of tetrakis(triphenylphosphine)palladium(0) (Pd(PPh₃)₄) thereto, the result was stirred for 15 hours at 80° C., and the reaction solution gradually changed to black. This was worked up, dried with magnesium sulfate, and then recrystallized to obtain Chemical Formula J (white powder, 4.3 g).

An NMR spectrum of the synthesized Chemical Formula J is presented in FIG. 4.

(2) Synthesis of Chemical Formula J-1

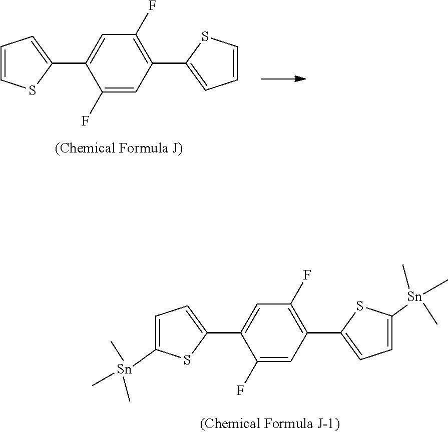

After dissolving the prepared Chemical Formula J in tetrahydrofuran (THF) and lowering the temperature to −78° C., 2.1 equivalents of n-butyllithium (n-BuLi) was added thereto, and the result was stirred for 30 minutes. After that, the result was further stirred for 1 hour at room temperature, and the solution color changed to yellow. The temperature was lowered to −78° C. again, 2.1 equivalents of trimethyltin chloride was added thereto, and the result was stirred for 12 hours while slowly raising the temperature to room temperature. After 12 hours, the solution color changed to ocher, and when crystallizing the result after work up, Chemical Formula J-1 in a glossy plate-type yellow solid form was obtained.

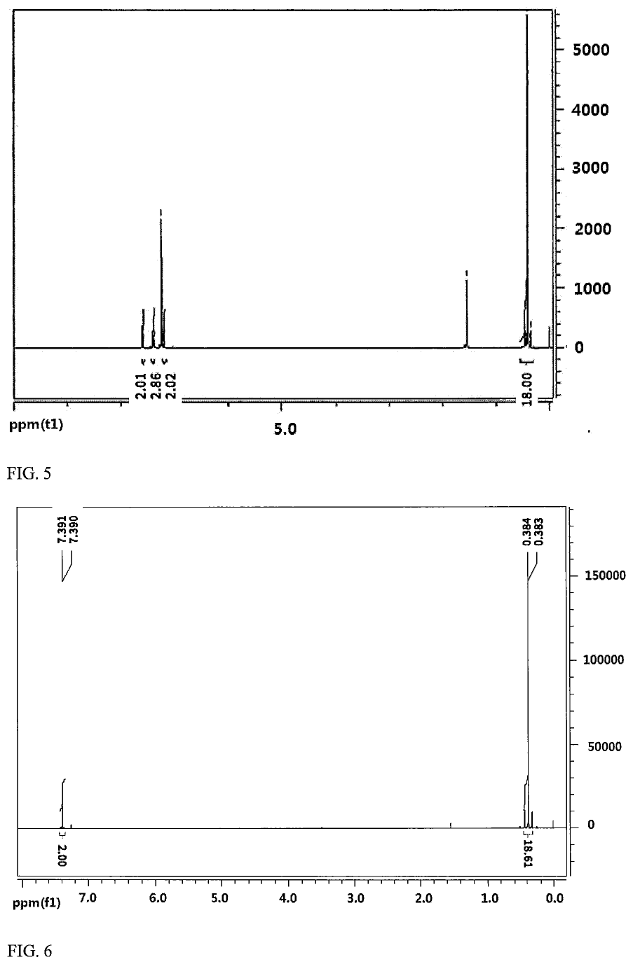

An NMR spectrum of the synthesized Chemical Formula J-1 is presented in FIG. 5.

(3) Synthesis of Chemical Formula K

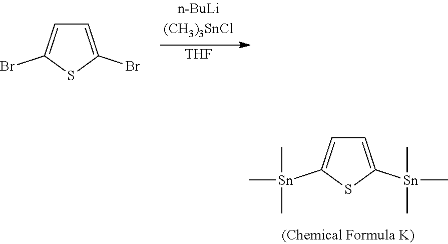

After introducing and dissolving 2,5-dibromothiophene (9.68 g, 40.0 mmol) in 200 ml of tetrahydrofuran (THF), the temperature was lowered to −78° C. At this temperature, 1.6 M n-butyllithium (n-BuLi) dissolved in hexane (55 ml, 88 mmol) was slowly added thereto, and the result was stirred for 1 hour. After that, 1 M trimethyltin chloride dissolved in THF (100 ml, 100 mmol) was introduced thereto at once, the temperature was raised to room temperature, and the result was stirred for 12 hours. This solution was poured into ice, extracted three times with diethyl ether and washed three times with water, and residual water was removed using magnesium sulfate (MgSO₄). With the remaining solution, the solvent was removed under decompression, and the result was recrystallized with methanol to obtain Chemical Formula K in a white solid form.

Yield: 73.1%

FIG. 6 presents an NMR spectrum of the synthesized Chemical Formula K.

(4) Synthesis of Chemical Formula L

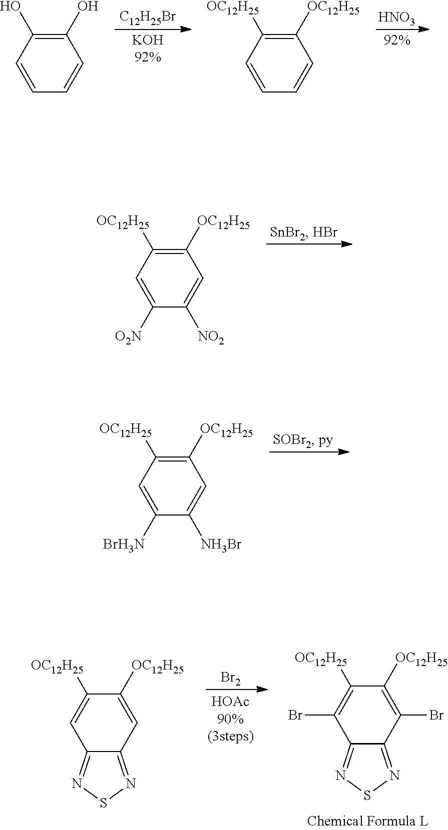

A compound of Chemical Formula L was synthesized based on JOURNAL OF POLYMER SCIENCE PART A: POLYMER CHEMISTRY 2011, 49, 4387-4397 4389.

(5) Synthesis of Polymer 1

The following Polymer 1 was prepared by, with chlorobenzene as a solvent, introducing the monomers of Chemical Formulae J-1, K and L with Pd₂(dba)₃ and P(o-tolyl)₃, and polymerizing the result using a microwave reactor.

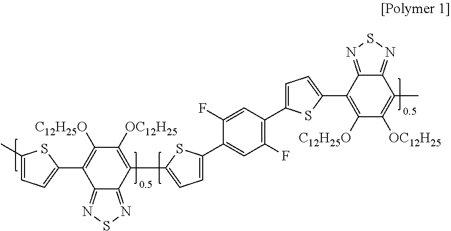

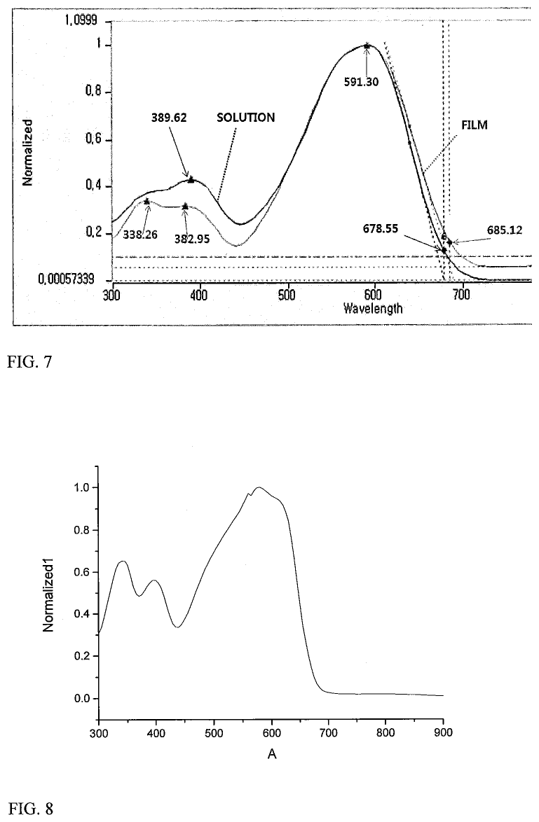

Properties of Polymer 1 are as in the following Table 1, and a UV-vis absorption spectrum of Polymer 1 is presented in FIG. 7.

TABLE 1

| | Polymer 1 | |
|---|---|---|
| Number Average Molecular Weight (Mn) | 21315 | g/mol |
| PDI (Molecular Weight Distribution: Mw/Mn) | 1.17 | |
| Color of Solid | Violet-Blue | |
| UV max (Solution State) | 591 | nm |
| UV max (Film State) | 591 | nm |
| UV edge (Film) | 685 | nm |
| Band Gap | 1.81 | eV |
| CV [Eox] | 1.18 V (Vs Ag/AgCl) | |
| HOMO Energy Level | −5.53 | eV |
| LUMO Energy Level | −3.72 | eV |

### Preparation Example 2: Synthesis of Polymer 2

(1) Synthesis of Chemical Formula M

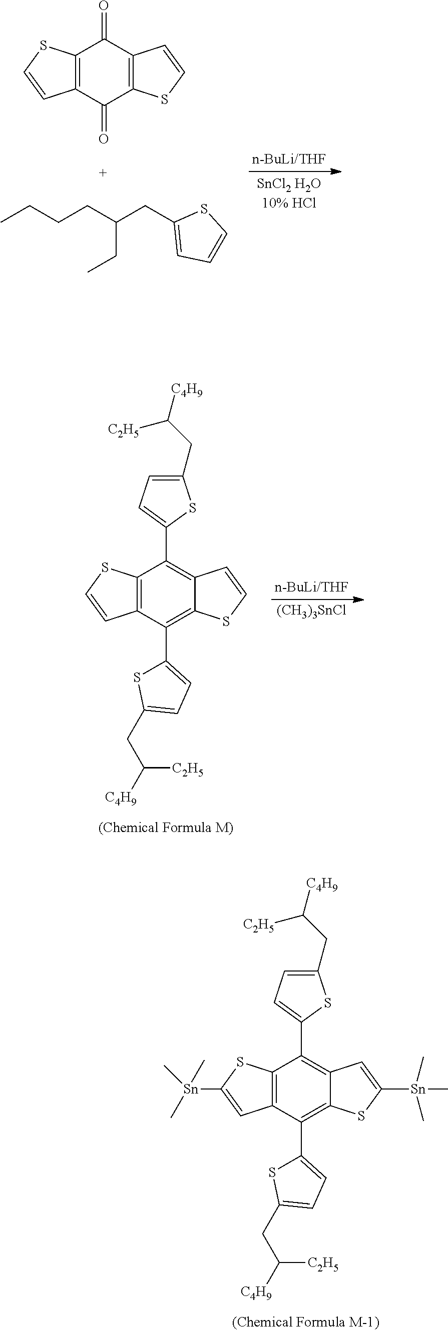

After introducing and dissolving 2-(2-ethylhexyl)thiophene (10.0 g, 59.4 mmol) in 500 ml of tetrahydrofuran (THF), the temperature was lowered to −78° C. At this temperature, 2.5 M n-butyllithium (n-BuLi) dissolved in hexane (24.0 ml, 59.4 mmol) was slowly added thereto, and the result was stirred for 30 minutes. After that, the temperature was raised up to 0° C., and after stirring the result for 1 hour in this state, 4,8-dihydrobenzo[1,2-b:4,5-b′]dithiophene-4,8-dione (3.3 g, 14.8 mmol) was introduced thereto at once, and the result was stirred for 3 hours 50° C. After lowering the temperature of this solution to room temperature, tin(II)chloride dehydrate (26 g) and 1 M HCl (56 ml) were added thereto, and the result was further stirred for 3 hours. Ice was poured into this solution, and the result was extracted twice with diethyl ether and washed twice with water, and residual water was removed using magnesium sulfate (MgSO₄). With the remaining solution, the solvent was removed under decompression, and Chemical Formula M in a yellow high density liquid form was obtained through silica column. (Yield: 64%)

(2) Synthesis of Chemical Formula M-1

After introducing and dissolving the compound of Chemical Formula M (3.9 g, 7.59 mmol) in 100 ml of tetrahydrofuran (THF), the temperature was lowered to 0° C. At this temperature, 1.6 M n-butyllithium (n-BuLi) dissolved in hexane (10.4 ml, 16.7 mmol) was slowly added thereto, and the result was stirred for 1 hour at room temperature. To this solution, 1 M trimethyltin chloride dissolved in THF (22.7 ml, 22.7 mmol) was introduced thereto at once, and the result was stirred for 2 hours. Water was poured into this solution, and the result was extracted twice with diethyl ether and washed twice with water, and residual water was removed using magnesium sulfate (MgSO₄). With the remaining solution, the solvent was removed under decompression, and the result was recrystallized with ethanol to obtain Chemical Formula M-1 in a light yellow crystalline form. (Yield: 87%)

(3) Synthesis of Polymer 2

The following Polymer 2 was prepared by, with chlorobenzene as a solvent, introducing Chemical Formulae J-1 and L synthesized in Preparation Example 1 and the monomer of Chemical Formula M-1 with Pd₂(dba)₃ and P(o-tolyl)₃, and polymerizing the result using a microwave reactor.

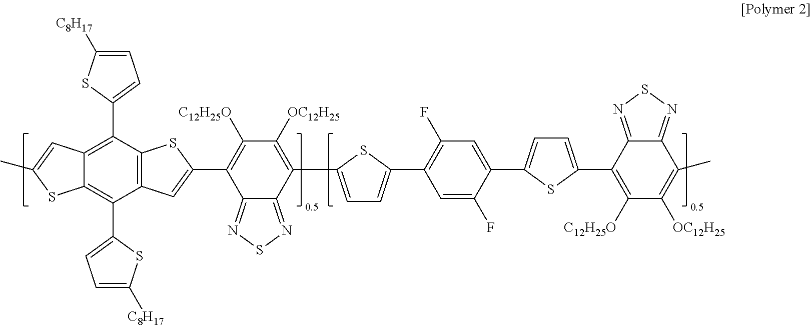

FIG. 8 is a diagram presenting a UV-vis absorption spectrum of Polymer 2.

### Example: Manufacture of Organic Solar Cell

### Example 1

ITO was formed on a substrate as a first electrode, and ZnO was spin-coated on the ITO to form an electron transfer layer. Then, a composite solution was prepared by dissolving 10 mg of Polymer 1 synthesized in Preparation Example 1 as an electron donor, and 20 mg of PC₇₁BM (Nano-C Inc, [NANO-C-PCBM-SF] 70PCBM) and the following ITIC (Solarmer Materials Inc.) as an electron acceptor in 1.5 ml of chlorobenzene (CB). Herein, a mass ratio of PC₇₁BM and ITIC was employed as 1.6:0.4. The composite solution was spin coated on the electron transfer layer to form a photoactive layer, and MoO₃ was deposited to a thickness of 10 nm on the photoactive layer to form a hole transfer layer. Lastly, in order to form a second electrode, Ag was deposited to a thickness of 100 nm using a thermal evaporator under vacuum of 3×10⁻⁸ torr to manufacture an organic solar cell.

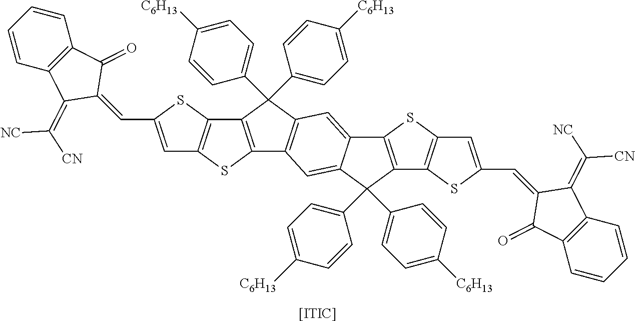

### Example 2

An organic solar cell was manufactured in the same manner as in Example 1 except that the mass ratio of PC₇₁BM and ITIC was employed as 1.2:0.8.

### Example 3

An organic solar cell was manufactured in the same manner as in Example 1 except that the mass ratio of PC₇₁BM and ITIC was employed as 0.8:1.2.

### Example 4

An organic solar cell was manufactured in the same manner as in Example 1 except that the mass ratio of PC₇₁BM and ITIC was employed as 0.5:1.5.

### Example 5

An organic solar cell was manufactured in the same manner as in Example 1 except that Polymer 2 synthesized in Preparation Example 2 was used instead of Polymer 1 as the electron donor, and the mass ratio of PC₇₁BM and ITIC was employed as 1.2:0.8.

### Example 6

An organic solar cell was manufactured in the same manner as in Example 5 except that the mass ratio of PC₇₁BM and ITIC was employed as 0.8:1.2.

### Example 7

An organic solar cell was manufactured in the same manner as in Example 5 except that the mass ratio of PC₇₁BM and ITIC was employed as 0.4:1.6.

### Example 8

An organic solar cell was manufactured in the same manner as in Example 5 except that the mass ratio of PC₇₁BM and ITIC was employed as 0.2:1.8.

### Comparative Example 1

An organic solar cell was manufactured in the same manner as in Example 1 except that only PC₇₁BM was used as the electron acceptor material.

### Comparative Example 2

An organic solar cell was manufactured in the same manner as in Example 1 except that only ITIC was used as the electron acceptor material.

### Comparative Example 3

An organic solar cell was manufactured in the same manner as in Example 5 except that only PC₇₁BM was used as the electron acceptor material.

### Comparative Example 4

An organic solar cell was manufactured in the same manner as in Example 5 except that only ITIC was used as the electron acceptor material.

Photoelectric conversion properties of the organic solar cells manufactured in Examples 1 to 8 and Comparative Examples 1 to 4 were measured under a 100 mW/cm² (AM 1.5) condition, and the results are shown in the following Table 2.

TABLE 2

| | Mass Ratio | | | | | | |
|---|---|---|---|---|---|---|---|
| | | Acceptor | | | J_{SC} | | |
| | Donor | PC₇₁BM | ITIC | V_{OC} (V) | (mA/cm²) | FF | PCE (%) |
| Example 1 | 1 | 1.6 | 0.4 | 0.875 | 13.797 | 0.670 | 8.09 |
| Example 2 | 1 | 1.2 | 0.8 | 0.890 | 15.042 | 0.653 | 8.74 |
| Example 3 | 1 | 0.8 | 1.2 | 0.896 | 15.665 | 0.636 | 8.94 |
| Example 4 | 1 | 0.5 | 1.5 | 0.899 | 15.448 | 0.584 | 8.11 |
| Example 5 | 1 | 1.2 | 0.8 | 0.896 | 14.437 | 0.623 | 8.05 |
| Example 6 | 1 | 0.8 | 1.2 | 0.898 | 15.984 | 0.630 | 9.04 |
| Example 7 | 1 | 0.4 | 1.6 | 0.899 | 15.603 | 0.623 | 8.73 |
| Example 8 | 1 | 0.2 | 1.8 | 0.910 | 14.885 | 0.639 | 8.65 |
| Comparative | 1 | 2 | 0 | 0.880 | 11.730 | 0.677 | 6.98 |
| Example 1 | | | | | | | |
| Comparative | 1 | 0 | 2 | 0.927 | 13.528 | 0.595 | 7.47 |
| Example 2 | | | | | | | |
| Comparative | 1 | 2 | 0 | 0.784 | 10.802 | 0.579 | 4.91 |
| Example 3 | | | | | | | |
| Comparative | 1 | 0 | 2 | 0.912 | 13.826 | 0.632 | 7.98 |
| Example 4 | | | | | | | |

In Table 2, V_{oc} means an open circuit voltage, Js means a short-circuit current, FF means a fill factor, and PCE means energy conversion efficiency. The open circuit voltage and the short-circuit current are each an x-axis and a y-axis intercept in the four quadrants of a voltage-current density curve, and as these two values increase, solar cell efficiency is preferably enhanced. In addition, the fill factor is a value dividing the rectangle area that may be drawn inside the curve by the product of the short-circuit current and the open circuit voltage. The energy conversion efficiency may be obtained when these three values are divided by intensity of the irradiated light, and it is preferred as the value is higher. FIG. 2 is a diagram presenting voltage-dependent current density of the organic solar cells of Example 3, Comparative Example 1 and Comparative Example 2. Through FIG. 2, it was seen that, when using Polymer 1 as an electron donor material, efficiency was higher when using PC₇₁BM and ITIC together as an electron acceptor material compared to when using PC₇₁BM or ITIC alone.

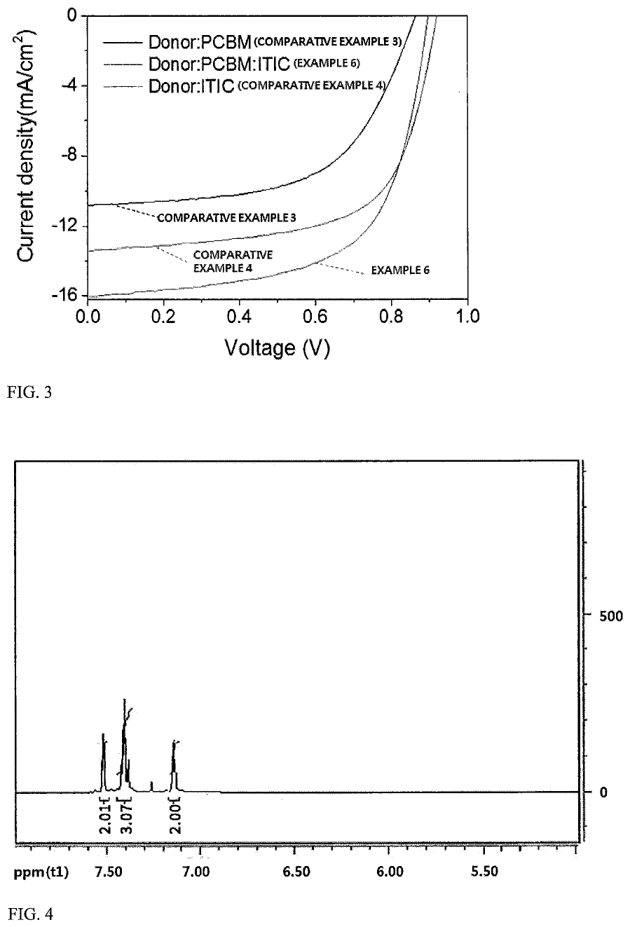

FIG. 3 is a diagram presenting voltage-dependent current density of the organic solar cells of Example 6, Comparative Example 3 and Comparative Example 4. Through FIG. 3, it was seen that, when using Polymer 2 as an electron donor material, efficiency was higher when using PC₇₁BM and ITIC together as an electron acceptor material compared to when using PC₇₁BM or ITIC alone.

In addition, through the results of Table 2, it was seen that higher energy conversion efficiency was obtained when using PC₇₁BM and ITIC together as an electron acceptor as in Examples 1 to 8 compared to Comparative Examples 1 to 4 using PC₇₁BM or ITIC alone.

1. An organic solar cell comprising:
a first electrode;
a second electrode on the first electrode; and
one or more organic material layers between the first electrode and the second electrode and including a photoactive layer,
wherein the photoactive layer includes an electron donor and an electron acceptor, and
the electron acceptor is a dual electron acceptor including both a fullerene-based compound and a non-fullerene-based compound.

2. The organic solar cell of claim 1, wherein the fullerene-based compound is selected from the group consisting of: [6,6]-phenyl-C₆₁-butyric acid methyl ester (PC₆₁BM), [6,6]-phenyl-C₇₁-butyric acid methyl ester (PC₇₁BM), mono-o-quino-dimethane C₆₀ (mono-oQDMC₆₀), bis-o-quino-dimethane C₆₀ (bis-oQDMC₆₀), indene-C₆₀-bis-adduct (ICBA) and bis-[6,6]-phenyl-C₆₁-butyric acid methyl ester (bis-PCBM):

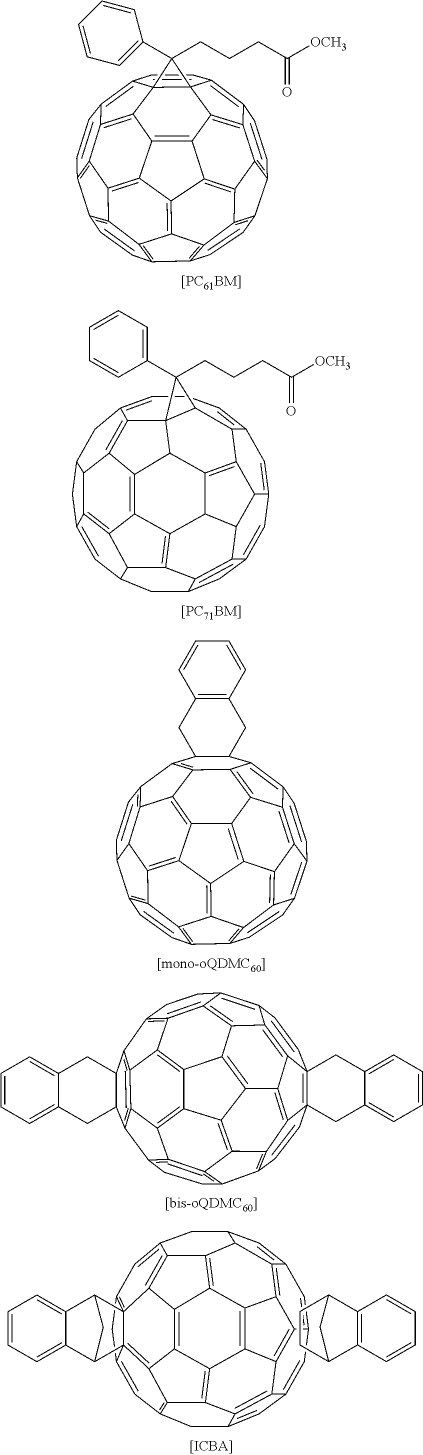

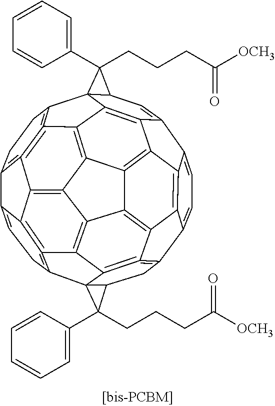

3. The organic solar cell of claim 1, wherein the non-fullerene-based compound is a compound of Chemical Formula A: 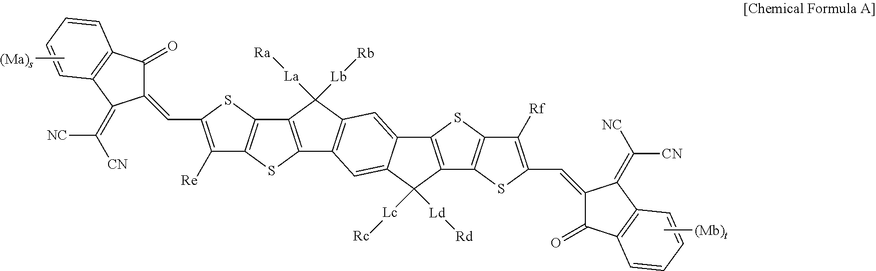
wherein:
Ra to Rf are the same as or different from each other, and each is independently hydrogen, or a substituted or unsubstituted alkyl group;
La to Ld are the same as or different from each other, and each is independently a substituted or unsubstituted arylene group, or a substituted or unsubstituted divalent heterocyclic group;
Ma and Mb are the same as or different from each other, and each is independently hydrogen, a halogen group, or a substituted or unsubstituted alkyl group;
s and t are the same as or different from each other, and each is independently an integer of 0 to 2; and
when s or t is 2, structures in the parentheses are the same as each other.

4. The organic solar cell of claim 3, wherein the compound of Chemical Formula A is any one of the following compounds of Chemical Formulae A-1 to A-5:

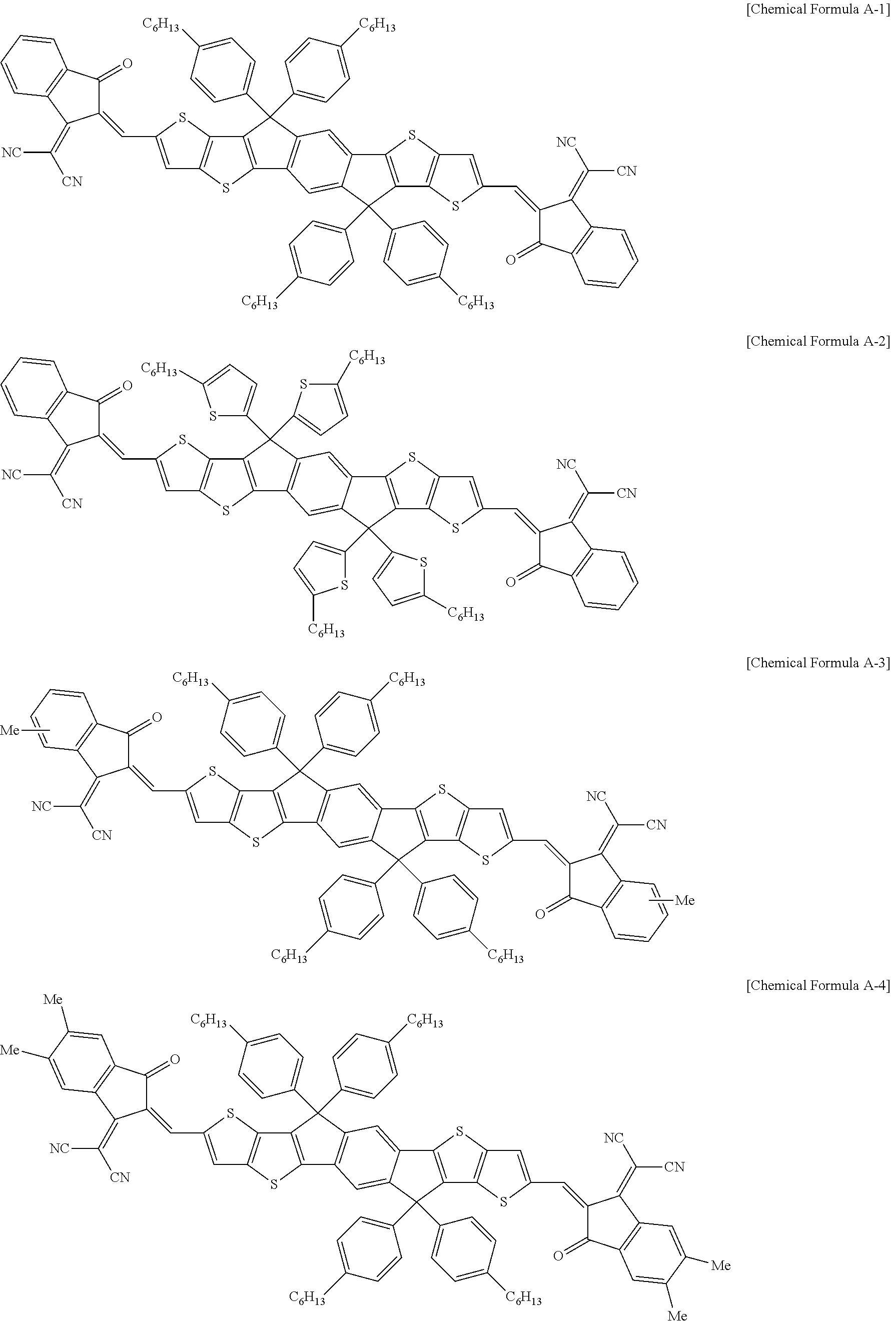

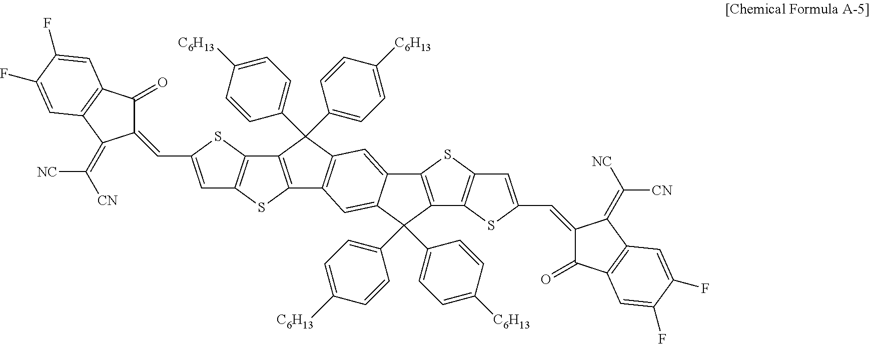

5. The organic solar cell of claim 1, wherein the electron donor comprises a polymer comprising a first unit of Chemical Formula 1 and a second unit of Chemical Formula 2: 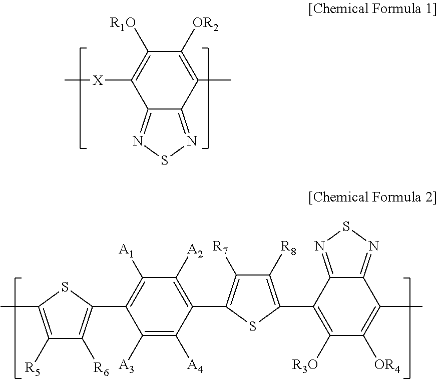
wherein:
X has the following Chemical Formula 3 or 4, 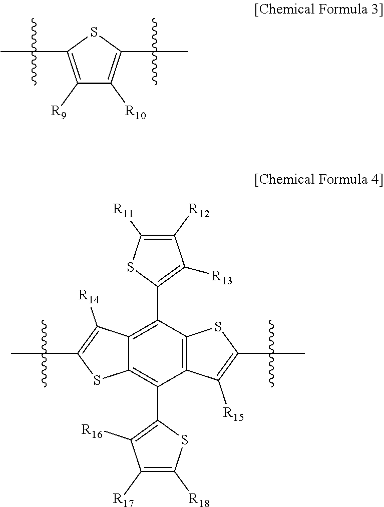
R₁ to R₄ are the same as or different from each other, and each is independently a substituted or unsubstituted alkyl group, or a substituted or unsubstituted aryl group;
R₅ to R₁₈ are the same as or different from each other, and each is independently hydrogen, deuterium, a halogen group, a nitrile group, a nitro group, a hydroxyl group, a substituted or unsubstituted alkyl group, a substituted or unsubstituted cycloalkyl group, a substituted or unsubstituted alkoxy group, a substituted or unsubstituted aryloxy group, a substituted or unsubstituted alkenyl group, a substituted or unsubstituted aryl group, or a substituted or unsubstituted heterocyclic group; and
A₁ to A₄ are the same as or different from each other, and each is independently hydrogen, fluorine or chlorine, and at least one of A₁ to A₄ is fluorine or chlorine.

6. The organic solar cell of claim 5, wherein the polymer comprises a unit of Chemical Formula 5: 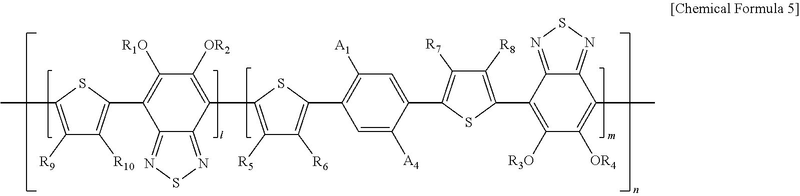
wherein:
R₁ to R₄ have the same definitions as in Chemical Formulae 1 and 2;
R₅ to R₁₀ have the same definitions as in Chemical Formulae 2 and 3;
A₁ and A₄ have the same definitions as in Chemical Formula 2;
l is, as a mole fraction, a real number of 0<l<1;
m is, as a mole fraction, a real number of 0<m<1;
l+m=1; and
n is, as a unit repetition number, an integer of 1 to 10,000.

7. The organic solar cell of claim 5, wherein the polymer comprises a unit of Chemical Formula 6: 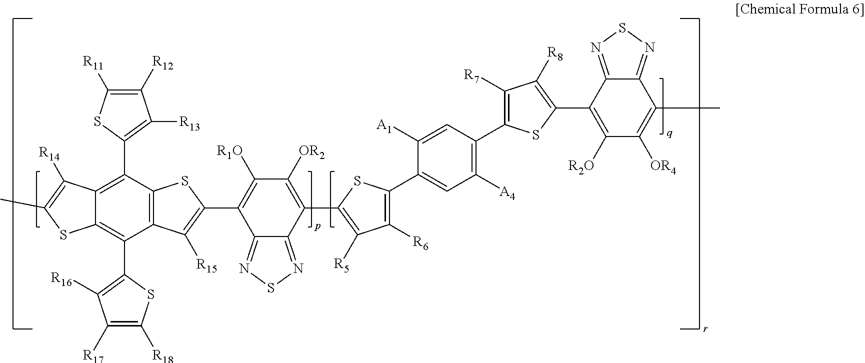
in Chemical Formula 6,
R₁ to R₄ have the same definitions as in Chemical Formulae 1 and 2;
R₅ to R₈ and R₁₁ to R₁₈ have the same definitions as in Chemical Formulae 2 and 4;
A₁ and A₄ have the same definitions as in Chemical Formula 2;
p is, as a mole fraction, a real number of 0<p<1;
q is, as a mole fraction, a real number of 0<q<1;
p+q=1; and
r is, as a unit repetition number, an integer of 1 to 10,000.

8. The organic solar cell of claim 1, wherein the fullerene-based compound and the non-fullerene-based compound have a mass ratio of 1.8:0.2 to 0.2:1.8.

9. The organic solar cell of claim 6, wherein the fullerene-based compound and the non-fullerene-based compound have a mass ratio of 1.6:0.4 to 0.5:1.5.

10. The organic solar cell of claim 7, wherein the fullerene-based compound and the non-fullerene-based compound have a mass ratio of 1.2:0.8 to 0.2:1.8.

11. The organic solar cell of claim 1, wherein the electron donor and the electron acceptor have a mass ratio of 1:1 to 1:4.

12. The organic solar cell of claim 1, wherein the electron donor and the electron acceptor form a bulk heterojunction (BHJ).

13. The organic solar cell of claim 5, wherein the polymer is a random polymer.

14. The organic solar cell of claim 5, wherein the polymer has a number average molecular weight of 5,000 g/mol to 1,000,000 g/mol.

15. The organic solar cell of claim 3, wherein Ra to Rd are each an alkyl group.

16. The organic solar cell of claim 6, wherein 1 and m are each 0.5.

17. The organic solar cell of claim 7, wherein p and q are each 0.5.

18. The organic solar cell of claim 1, wherein the organic solar cell further comprises a substrate, a hole transfer layer and/or an electron transfer layer.
